(19) United States
(12) Patent Application Publication
(10) Pub. No.: US 2008/0084675 A1
(43) Pub. Date: Apr. 10, 2008

(54) Structure for holding a printed circuit board assembly

(76) Inventors: Muhammad H. Amirali, Northridge, CA (US); Lee C. Gumprecht, Camarillo, CA (US); The Pham, Siimi Valley, CA (US); Frits E. Kitzmann, Simi Valley, CA (US); Robert K. Coleman, Moorpark, CA (US); Heng-Kit Too, Oak Park, CA (US)

Correspondence Address: FISH & RICHARDSON P.C., P.O. BOX 1022, MINNEAPOLIS, MN, 55440-1022, US

(21) Appl. No.: 11/543,687

(22) Filed: Oct. 5, 2006

(51) Int. Cl. H05K 5/00

(52) U.S. Cl. 361/752

(57) ABSTRACT

An apparatus is for holding a circuit board having components attached to a top surface and to a bottom surface of the circuit board. The apparatus includes a structure having at least two sides, each of which has a ledge that protrudes from a side of the structure for supporting the circuit board. The ledge has a height that exceeds a distance between the circuit board and a bottom of a first component mounted on the bottom surface of the circuit board such that structure suspends the first component above a surface holding the structure.

### TECHNICAL FIELD

This patent application relates generally to a structure for holding a printed circuit board assembly (PCBA).

### BACKGROUND

A PCBA can include a printed circuit board (PCB) and components mounted on the top and/or the bottom of the PCB. During handling (e.g., processing, shipment, etc.), a PCBA is often subjected to various types of stress, which can adversely affect the PCBA. For example, shear stress applied to the PCBA can damage one or more components of the PCBA or even cause one or more components to detach from the PCBA. Flexural stress can cause the PCBA to crack or break. Larger PCBAs are particularly susceptible to these types of damage.

### SUMMARY

This patent application is directed to a structure for holding a PCBA, and to a system that uses that structure.

In one aspect, this application is directed to an apparatus for holding a circuit board having components attached to a top surface and to a bottom surface of the circuit board. The apparatus comprises a structure comprising at least two sides. Each of the at least two sides has a ledge that protrudes from a side of the structure, each ledge for supporting the circuit board. The ledge has a height that exceeds a distance between the circuit board and a bottom of a first component mounted on the bottom surface of the circuit board such that structure suspends the first component above a surface holding the structure. The apparatus may also include one or more of the following features.

A distance between a top of the structure and the ledge may exceed a distance between the circuit board and a top of a second component mounted on the top surface of the surface board. The structure may comprises a frame having four sides, each which may have a ledge that protrudes from a side of the frame for supporting the circuit board. At least one of the four sides may be movable relative to the other three sides so as to enable the circuit board to fit inside the frame. The apparatus may comprise a hinged connection between the at least one of the four sides and the frame.

The structure may have a dimension of at least 16 inches by 18 inches, and may accommodate a circuit board having a dimension of 16 inches by 18 inches. The structure may comprise a composite plastic material and/or metal, such as aluminum. The apparatus may comprise a bottom surface. The bottom surface may be fixed to a bottom of the structure.

In another aspect, this application is directed to a system for holding circuit boards. The system comprises a first apparatus for holding a first circuit board having components attached to a top surface and to a bottom surface of the first circuit board. The first apparatus comprises a first structure comprising at least two first sides. Each of the at least two first sides has a first ledge that protrudes from a side of the structure. Each first ledge is for supporting the first circuit board. The first ledge has a height that exceeds a distance between the first circuit board and a bottom of a first component mounted on the bottom surface of the first circuit board.

The system also comprises a second apparatus for holding a second circuit board having components attached to a top surface and to a bottom surface of the first circuit board. The second apparatus comprises a second structure comprising at least two second sides. Each of the at least two second sides has a second ledge that protrudes from a side of the structure. Each second ledge is for supporting the second circuit board. The second ledge has a height that exceeds a distance between the second circuit board and a bottom of a second component mounted on the bottom surface of the second circuit board. The first apparatus stacks atop the second apparatus.

The details of one or more examples are set forth in the accompanying drawings and the description below. Further features, aspects, and advantages will become apparent from the description, the drawings, and the claims.

### DESCRIPTION OF THE DRAWINGS

FIG. 1A is a block diagram of a structure for holding a PCBA.

FIG. 1B is a cross-sectional view of the structure of FIG. 1A.

FIG. 2 is a block diagram of a structure for holding a PCBA that includes a bottom.

FIG. 3 is a block diagram of a structure for holding a PCBA, which shows one side of the structure in an opened position.

FIG. 4 is a block diagram of another implementation of structure for holding a PCBA.

FIG. 5A shows a cross-section of a PCBA mounted in a structure for holding a PCBA, such as that of FIG. 1 or FIG. 4.

FIG. 5B shows a cross-section of a PCBA mounted in structure for holding a PCBA, which is placed on a flat support surface.

FIG. 6 shows structures for holding PCBAs stacked one on top of the other.

Like reference numerals in different figures indicate like elements.

### DETAILED DESCRIPTION

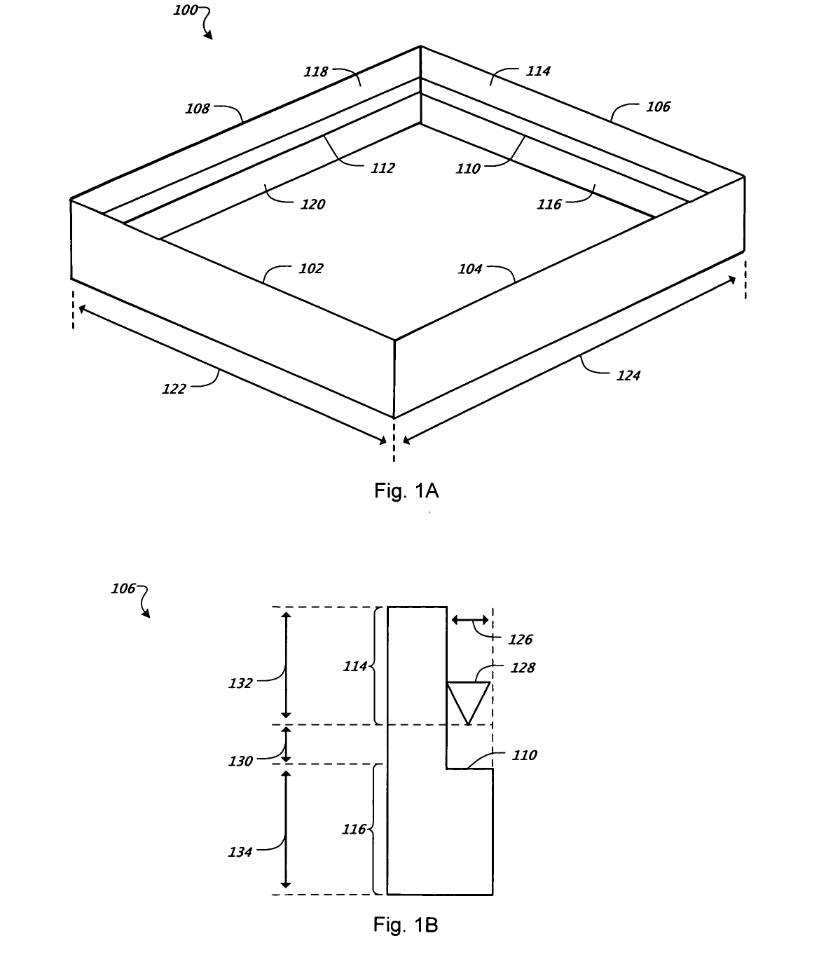

FIG. 1A is a block diagram of a structure for holding a PCBA (hereinafter a “PCBA holding structure”). The structure can include four sides 102, 104, 106 and 108 which, when fitted together, form a frame 100. Each side can include a ledge that protrudes from it and a peripheral part adjacent to the top and bottom surface of the ledge. The ledge can be located in the center of each inward-facing side. FIG. 1A shows ledge 110 located on side 106 and ledge 112 located on side 108. Sides 102 and 104 contain similar ledges, which are not shown in FIG. 1A. Each of these four ledges line-up when the sides are connected to form frame 100, thereby forming a continuous four sided ledge, which defines a platform. A PCBA can be held on this platform, as explained below.

Top part 114 and bottom part 116 are adjacent to the top and bottom portions of ledge 110. Ledge 112 also has an adjacent top part 118 and an adjacent bottom part 120. Sides 102 and 104 also include similar top and bottom parts.

Side 102 of frame 100 can be of length 122. Side 104 of frame 100 can be of length 124. Parallel sides of the frame may be of the same length. In one implementation of frame 100, length 122 may be equal to length 124. In another implementation, length 122 and length 124 may be different. In one implementation, in order to accommodate a PCBA that is of dimensions 16 inches by 18 inches, length 122 may be at least 16 inches and length 124 can be at least 18 inches. Frame 100 can be used for, but is not limited to, holding relatively large PCBAs, e.g., which are greater than 8 inches by 10 inches in size.

FIG. 1B is a cross-sectional view of side 106 of frame 100. Side 106 includes ledge 110, top part 114 and bottom part 116. A ledge width 126 can correspond to, e.g., the amount of area around the edge of a PCBA that is unpopulated, e.g., an area that contains no components. The ledge width 116 can also correspond to, e.g., the amount of unpopulated area around the edge of a PBCA that is needed to physically hold the PCBA on the platform of structure 100. This size and weight of the PCBA may also affect the structure, e.g., the ledge width, needed to hold the PCBA.

A constraint 128 can be placed on the top part 114. Constraints can be placed at various locations along each side of frame 100, e.g., along the top parts, in order to hold a PCBA in place. This can help in reducing the amount of flexing, or bending, of the PCBA that can occur in handling, e.g., from manufacturing through testing. The constraints can be, e.g., metal or non-metal clips that are placed at intervals along the top part of the frame to keep the PCBA substantially stationary within frame 100.

A ledge height 130 can be the distance from ledge 110 to the bottom of a constraint 128. The ledge height 130 can be determined from the thickness of the PCB. The ledge height 130 can then be used to determine the location of the constraints along the top part in the frame with respect to the ledge. The thickness of a PCB can vary depending, for example, on how many layers are included in the PCB.

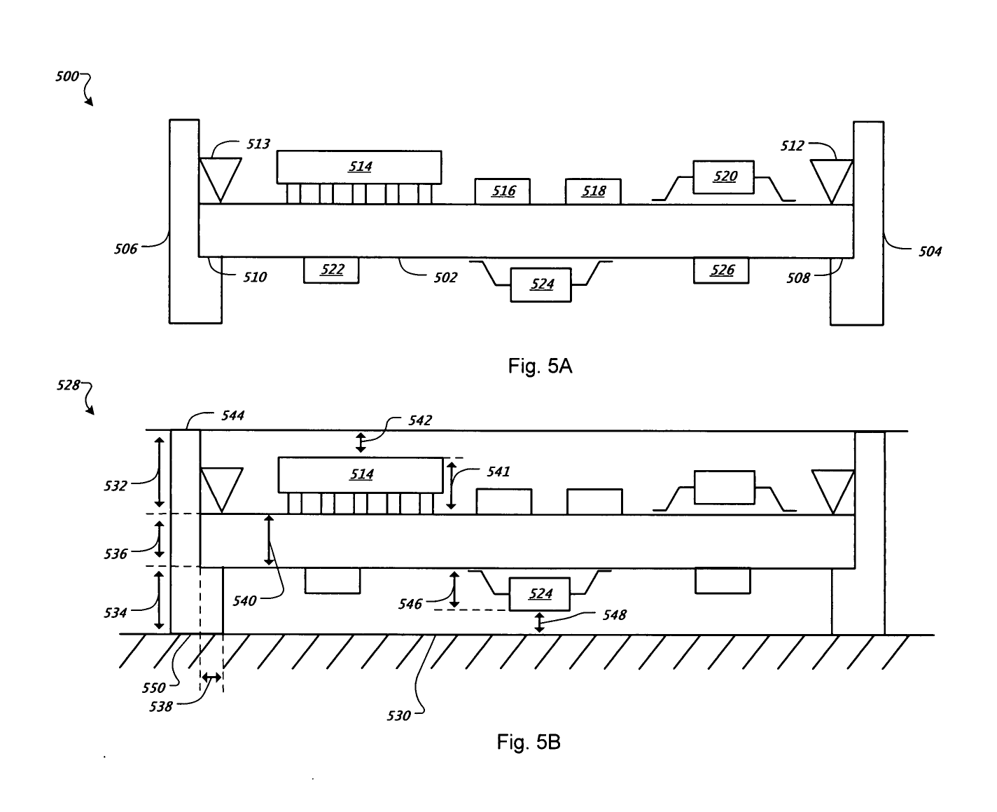

A top part height 132 can be the length from the top of side 106 to the bottom of constraint 128. A bottom part height 134 can be the length from ledge 110 to the bottom of side 106. Top part height 132 and bottom part height 134 can be determined based on the height of the components on the PCBA. For example, top part height 132 and bottom part height 134 can be chosen to allow the PCBA to be mounted in frame 100 and placed on a flat surface without any of the PCBA components coming in contact with the flat surface. This is described in more below with respect to FIGS. 5A and 5B.

Frame 100 can comprise, in part or whole, a material that exhibits anti-static properties. In this regard, static discharge during PCBA handling can cause damage to components on the PCBA, causing the board to fail during test or later-on, in the field. Therefore, frame 100 can be comprised of a material designed to eliminate all or some static discharge that may occur during handling. A metal, such aluminum, or a composite plastic material, such as Delmat™, may be used to construct frame 100.

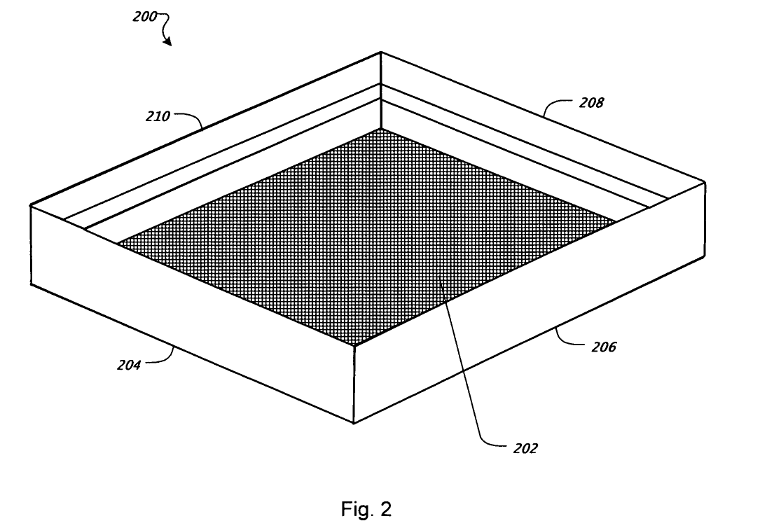

FIG. 2 is a block diagram of a PCBA holding structure that includes a bottom surface 202. Frame 200 can include sides 204, 206, 208 and 210. The sides can be as described above with respect to FIG. 1A. Bottom surface 202 can be included, e.g., when a PCBA has components on the top side and no components on the bottom side. In this case, bottom surface 202 may act as added protection for the bottom of the PCBA. Frame 200 can be constructed in a similar manner as the frame described in FIG. 1A, and such that bottom surface 202 does not contact with the PCBA. In an alternative implementation (not shown), a top surface may be included on the PCBA holding structure. The top surface may contain a hinged side that enables it to be opened to view the PCBA. Alternatively, the top surface may be fully removable.

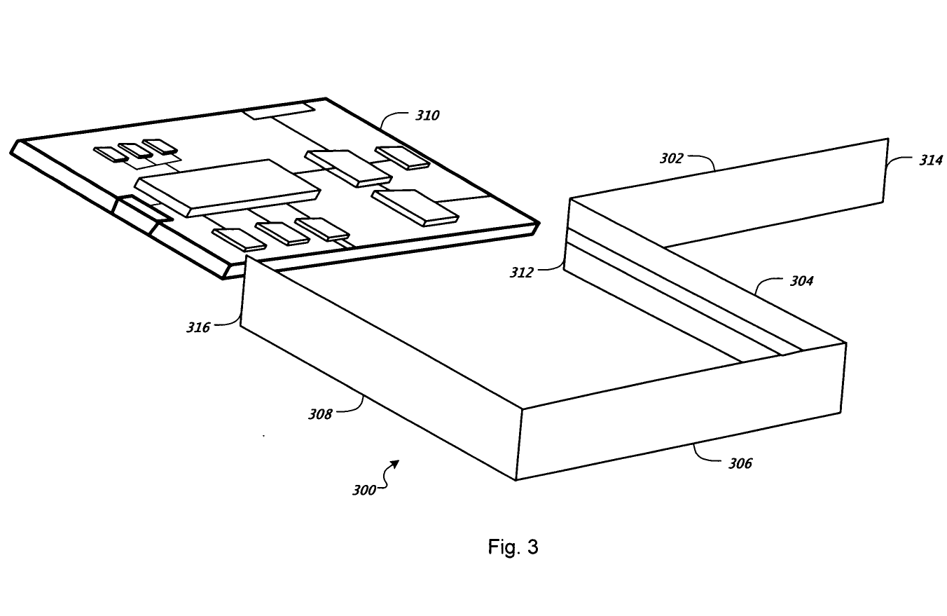

FIG. 3 is a block diagram of a PCBA holding structure with one side in an opened position. Frame 300 can include sides 302, 304, 306 and 308. Frame 300 can be constructed in a similar manner to frame 100, described with respect to FIG. 1A. However, side 302 can be movable relative to the remainder of the frame, thereby allowing a PCBA 310 to be inserted into frame 300. In one implementation, side 302 can be attached to the frame 300 in such a way as to allow it to be moved but not detached from the frame 300. This can be done, e.g., by using a hinge 312 that can connect side 302 to the frame 300. Interlocking latches 314 and 316 can be located on sides 302 and 308, respectively, that allow side 302 to close and latch to side 308 once PCBA 310 has been inserted into the frame 300. In an alternative implementation (not shown) side 302, or any other side or sides, may be completely detachable from the frame.

PCBA 310 can be slid onto the ledges and below the constraints of sides 304, 306 and 308. Once in place, side 302 can be closed to connected to the remainder of the frame, and thereby contact the remaining side of PCBA 310 (the bottom of PCBA 310 rests on the ledge of side 302). Interlocking latches 314 and 316 can be connected to provide a closed frame 300 that engages and supports PCBA 310.

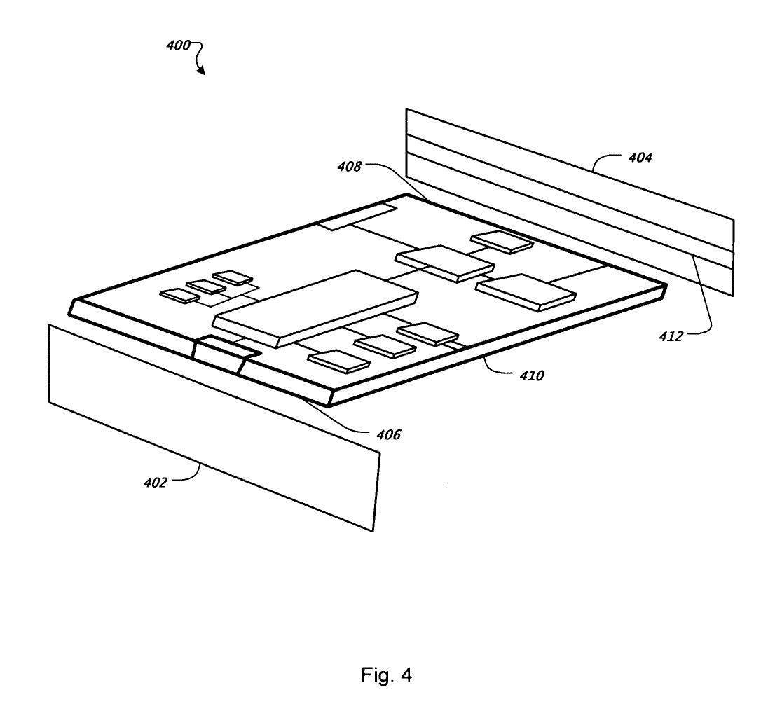

FIG. 4 is a block diagram of an alternate implementation of a PCBA holding structure. In this implementation, structure 400 includes two sides 402 and 404. Sides 402 and 404 can be of the type shown and described with reference to FIG. 1A. Side 404 can include ledge 412 and side 402 can include a similar ledge (not shown). Sides 402 and 404 can also include constraints as described with reference to FIG. 1B, and may or may not be connected. Sides 402 and 404 can attach to edges 406 and 408 respectively of PCBA 410. Sides 402 and 404 can support PCBA 410, allowing it to be placed on a flat surface, such as a table top, without any of the components on the bottom side of the PCBA making contact with the table top. In still other implementations (not shown), the PCBA holding device may include only three sides, or more than four sides.

FIG. 5A shows a cross-section 500 of a PCBA 502 mounted in a PCBA holding structure. Cross-section 500 shows sides 504 and 506 containing ledges 508 and 510 respectively. PCBA 502 can be placed on ledges 508 and 510 and held in place by constraints 512 and 513. Additional constraint(s) can be located at intervals on the sides of the PCBA holding structure. Cross-section 500 can be a PCBA holding structure as described with reference to FIG. 1A, where the structure includes a four-sided frame, or as described with respect to FIG. 4, where the structure includes a two-sided frame.

PCBA 502 can include components mounted on both sides of the PCBA. Here, components 514, 516, 518 and 520 are mounted on a top of PCBA 502, and component 514 is the tallest. Components 522, 524 and 526 are mounted on the bottom of the PCBA, and the tallest component there is component 524.

FIG. 5B shows a cross-section 528 of PCBA 502 mounted in a PCBA holding structure that is placed on a flat support surface 530. The PCBA holding structure allows PCBA 502 to be placed on a flat support surface 530, such as a table top, such that the tallest component 524 does not make contact with the table top.

The PCBA holding structure can be customized to accommodate any type of PCBA. For example, top part height 532, bottom part height 534, ledge height 536, and ledge width 538 can be designed to accommodate any sized/shaped PCBA 502.

Ledge height 536 can be designed based on a PCBA thickness 540. Ledge width 538 can be designed based on the amount of area along the edges of the PCBA that does not contain any components, as well as how much of the unpopulated edge of the PCBA needs to be placed on the ledges of the PCBA holding structure to allow the PCBA to be adequately supported by the structure. For example, the ledge width 538 can be designed based on the overall size and weight of the PCBA 502.

The top part height 532 can be determined by adding a height 541 of the tallest component 514 on the top side of the PCBA 502 to the amount of clearance 542 needed from the top of the tallest component 514 to the top of the part 544. In a similar manner, the bottom part height 534 can be determined by adding the height 546 of the tallest component 524 on the bottom side of the PCBA 502 to the amount of clearance 548 needed from the top of the tallest component 524 to the bottom of the part 550.

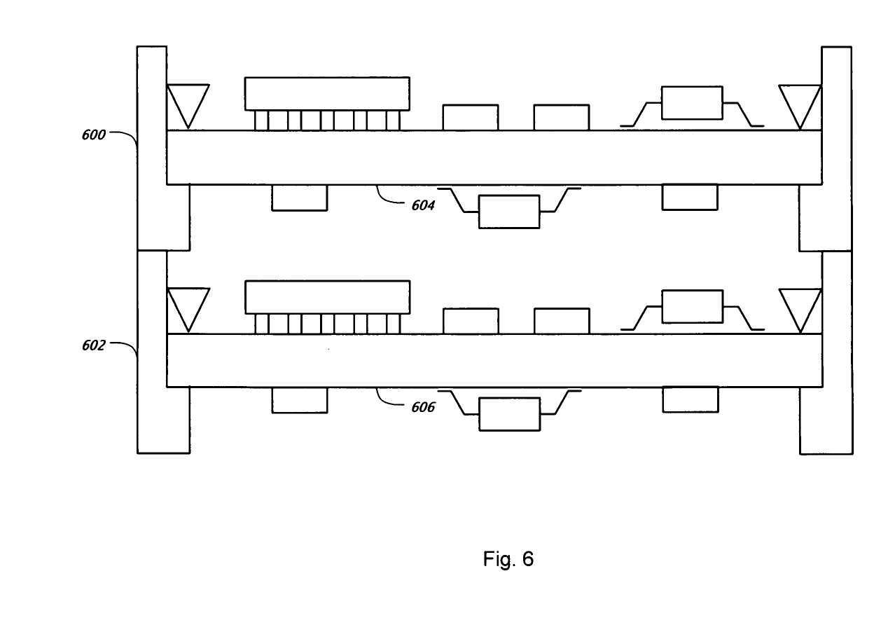

FIG. 6 shows a cross-section of a PCBA holding structure 600 stacked atop another PCBA holding structure 602. The design and construction of this PCBA holding system enables a PCBA 604 mounted in a test structure 600 to be stacked atop another PCBA 606 mounted in a test structure 602. The sides of the test structure can provide the support needed to keep the PCBA rigid, while also providing the separation needed between the bottom side components of the top PCBA 604 and the top side components of the bottom PCBA 606. Although FIG. 6 shows two PCBA holding structures, any number of structures may be stacked one on top of the other. It is noted that the number of structures that may be stacked may be limited by the weight of the PCBA and the rigidity of the design of the PCBA holding structure.

The PCBA holding structure can be customized for a PCBA based on the dimensions, weight and width of the PCBA, as well as the amount of clearance needed from the tallest components on either side (top or bottom) of the PCBA.

The PCBA holding structure can provide protection to a PCBA by constraining the perimeter of the PCBA, and by providing clearance to components on the top and bottom of the PCBA. The PCBA holding structure limits flexural excitation of the PCBA, namely the flexing, bending or warping of the PCBA that can occur when handling the PCBA. The PCBA may be handled, for example, during intermediate manufacturing and test steps such as press-fit, manual assembly, and reworking. Constraining the perimeter of the PCBA can protect it from damage due to flexural excitation.

The PCBA holding structure can provide additional protection to a PCBA by limiting the amount of shear stress applied to the PCBA. Shear stress to a component can occur when the component is slid, for example, against a flat surface. Providing clearance to the tallest components on both the top side and the bottom side of the PCBA allows the PCBA to be placed on a flat surface on either side for, e.g., manual assembly or rework, without permitting the components to contact the flat surface.

Shear stress, as well as flexural excitation, can result in damage to the PCBA itself (e.g., the board can crack) and/or to components and/or the solder joints, or connections, on the PCBA. This damage can result in the immediate failure of the board during testing. This damage can also remain undetected, however, resulting in an early failure of the PCBA once in the field.

The PCBA holding structure can be designed, as described with reference to FIG. 1A, with the top and bottom of the structure opened. This can allow testers to use the PCBA holding structure as their test structure, since the components and the PCBA are accessible. Also, the PCBA holding structure can allow for complete surface access for top and bottom side troubleshooting after testing.

The foregoing features of the PCBA holding structure permit its use from the time when the PCBA exits a reflow oven, through testing, and cleaning until the PCBA is secured in a box, or instrument. A lightweight design of the PCBA holding structure can enable a PCBA mounted in the PCBA holding structure to be shipped in a container, while keeping the PCBA relatively rigid and safe during shipping.

It is noted that the PCBA holding structure can be used during in-circuit and module level testing. That is, the structure can hold a PCBA during actual testing without requiring removal of the PCBA during testing. As a result, stability during testing is increased, and the chances of damage to the PCBA during testing are decreased.

Elements of different implementations described herein may be combined to form other implementations not specifically set forth above. Other implementations not specifically described herein are also within the scope of the following claims.

What is claimed is:

1. An apparatus for holding a circuit board having components attached to a top surface and to a bottom surface of the circuit board, the apparatus comprising:
a structure comprising at least two sides, each of the at least two sides having a ledge that protrudes from a side of the structure, each ledge for supporting the circuit board;
wherein the ledge has a height that exceeds a distance between the circuit board and a bottom of a first component mounted on the bottom surface of the circuit board such that structure suspends the first component above a surface holding the structure.

2. The apparatus of claim 1, wherein a distance between a top of the structure and the ledge exceeds a distance between the circuit board and a top of a second component mounted on the top surface of the surface board.

3. The apparatus of claim 1, wherein the structure comprises a frame having four sides, each of the sides having a ledge that protrudes from a side of the frame for supporting the circuit board.

4. The apparatus of claim 3, wherein at least one of the four sides is movable relative to the other three sides so as to enable the circuit board to fit inside the frame.

5. The apparatus of claim 4, further comprising a hinged connection between the at least one of the four sides and the frame.

6. The apparatus of claim 1, wherein the structure has a dimension of at least 16 inches by 18 inches, and can accommodate a circuit board having a dimension of 16 inches by 18 inches.

7. The apparatus of claim 1, wherein the structure comprises a composite plastic material.

8. The apparatus of claim 1, wherein the structure comprises metal.

9. The apparatus of claim 8, wherein the metal comprises aluminum.

10. The apparatus of claim 1, further comprising a bottom surface, the bottom surface being fixed to a bottom of the structure.

11. A system for holding circuit boards, the system comprising:
a first apparatus for holding a first circuit board having components attached to a top surface and to a bottom surface of the first circuit board, the first apparatus comprising:
a first structure comprising at least two first sides, each of the at least two first sides having a first ledge that protrudes from a side of the structure, each first ledge for supporting the first circuit board;
wherein the first ledge has a height that exceeds a distance between the first circuit board and a bottom of a first component mounted on the bottom surface of the first circuit board; and
a second apparatus for holding a second circuit board having components attached to a top surface and to a bottom surface of the first circuit board, the second apparatus comprising:
a second structure comprising at least two second sides, each of the at least two second sides having a second ledge that protrudes from a side of the structure, each second ledge for supporting the second circuit board;
wherein the second ledge has a height that exceeds a distance between the second circuit board and a bottom of a second component mounted on the bottom surface of the second circuit board;
wherein the first apparatus stacks atop the second apparatus.
